(19) United States
(12) Patent Application Publication
(10) Pub. No.: US 2021/0066407 A1
(43) Pub. Date: Mar. 4, 2021

(54) Method and Apparatus for Direct Patterning of High-Resolution OLED Microdisplays

(71) Applicant: eMagin Corporation, Hopewell Junction, NY (US)

(72) Inventors: Amalkumar P. GHOSH, Hopewell Junction, NY (US); Qi WANG, Hopewell Junction, NY (US); Ilyas I. KHAYRULLIN, Hopewell Junction, NY (US); Fangchao ZHAO, Hopewell Junction, NY (US); Tariq ALI, Hopewell Junction, NY (US); Andrew G. SCULLEY, JR., Martinez, CA (US)

(21) Appl. No.: 17/013,019

(22) Filed: Sep. 4, 2020

Related U.S. Application Data
(60) Provisional application No. 62/895,688, filed on Sep. 4, 2019.

(51) Int. Cl. H01L 27/32; H01L 51/56

(52) U.S. Cl. CPC H01L 27/3218; H01L 51/56; H01L 27/3216

(57) ABSTRACT

OLED-based displays that include pixel arrays having non-uniform sub-pixel arrangements are presented. The non-uniformity of the sub-pixel arrangements enable the pattern of light-emitting material for each sub-pixel color to be deposited through a structurally robust, high-resolution shadow mask in a single deposition. Sub-pixel arrangements in accordance with the present disclosure have larger separations between adjacent features and, therefore, shadow masks suitable for use in forming an entire same-color sub-pixel pattern have apertures that are separated by more structural material. As a result, such shadow masks have greater structural integrity than shadow masks known in the prior art. The teachings of the present disclosure are particularly well suited for the fabrication of full-color, high-resolution, side-by-side-type OLED displays that have a pixel pitch of 20 microns or less.

### STATEMENT OF RELATED CASES

This application claims priority to U.S. Provisional Patent Application Ser. No. 62/895,688, filed Sep. 4, 2019, the entirety of which is incorporated herein by reference.

### TECHNICAL FIELD

The present disclosure relates to semiconductor processing in general, and, more particularly, to direct deposition of patterns of organic light-emitting material via shadow-mask-based material deposition.

### BACKGROUND

The active-matrix organic light-emitting diode (AMOLED) micro-display market has grown rapidly in recent years because AMOLED displays can have higher brightness, higher resolution, longer lifetime, and higher contrast, than other display technologies. However, achieving high resolution for full-color displays (i.e., red, green and blue) with high brightness remains a challenge.

Conventional AMOLED displays capable of full-color light emission typically have one of two structural arrangements. In a first approach, each display pixel includes a plurality of independently addressable white OLED on pixelated anodes, each anode defining a different sub-pixel. Different color filters are disposed on these white-light sub-pixel emitters so that only the desired color (e.g., red, green, and blue) is transmitted, while all other colors in the white light emitted by the sub-pixel are absorbed. Although this approach enables relatively simple device processing, such displays are extremely inefficient because nearly 80% of the emitted optical energy is not transmitted. In addition, the absorbed light is converted to heat, creating thermal-management issues.

In a second approach, each display pixel includes sub-pixels made of independently addressable, directly patterned, red, green and blue OLEDs, which are located side-by-side within each pixel. This “side-by-side” arrangement has better device efficiency since each sub-pixel emits only its desired red, green, or blue light when it is energized; therefore, little of the emitted light is wasted. As a result, the side-by-side arrangement is typically viewed as more favorable for high-brightness AMOLED displays.

Unfortunately, patterning the organic light-emitting material to define the OLED sub-pixels of a high-resolution display (>2500 pixels per inch) can be challenging. Due to the organic nature of the organic light-emitting materials, they cannot be deposited as a full-surface layer and subsequently patterned via conventional lithographic and etching methods. As a result, the OLED-material patterns must be directly deposited by evaporating it through a shadow-mask having an appropriate pattern of apertures. However, the very close spacing between adjacent apertures leaves very little structural mask material between them, making it difficult to fabricate and use such shadow masks.

In the prior art, therefore, each color-emitting sub-pixel array is typically formed using multiple depositions through a sparser shadow mask, where the patterns defined by each deposition are interleaved to form the complete array of sub-pixels. For two interleaved depositions, for example, the density of the aperture pattern of the shadow mask is cut in half, resulting in more structural material between the apertures.

Unfortunately, the need for multiple depositions for each light-emitting material creates problems, particularly for mass production, because (1) it significantly increases fabrication time, thereby decreasing the product throughput, and (2) it wastes costly organic light-emitting material, thereby increasing cost. Furthermore, the multiple depositions must be carefully aligned to avoid causing optical artifacts in the resultant displays.

The need for an efficient, low-cost approach for forming a high-resolution OLED display remains, as yet, unmet in the prior art.

### SUMMARY

The present disclosure is directed toward the fabrication of high-resolution OLED displays based on “side-by-side” pixels using direct patterning of the color-emitting materials of the sub-pixels. Embodiments in accordance with the present disclosure enable the formation of the complete pattern of each color-emitting layer in a single deposition through a shadow mask.

Like OLED displays known in the prior art, displays in accordance with the present disclosure employ a side-by-side sub-pixel arrangement in their pixels.

In sharp contrast to the prior art, however, the sub-pixels are not uniformly arranged in all of the pixels of a display in accordance with the present disclosure. By using a non-uniform sub-pixel arrangement:
(1) the aperture pattern of a shadow mask to be sparser such that the apertures are separated by larger regions of structural mask material; and
(2) all sub-pixels of the same color-emitting material can be deposited via direct deposition using a single deposition.

An illustrative embodiment in accordance with the present disclosure is a high-resolution OLED display comprising a two-dimensional array of pixels that are arranged in a plurality of rows and columns, where the position of the sub-pixels of one color along each row is not same. Specifically, each pixel includes one green sub-pixel, one red sub-pixel, and one blue sub-pixel, which arranged in a 1×3 sub-pixel array. Across each row of pixels of the display, the position of the sub-pixels of each color alternates between two different sub-pixel positions within the sub-pixel array.

In some embodiments, the same-color sub-pixels are arranged such that they index by one sub-pixel position from pixel to pixel along each row (i.e., they are arranged diagonally along the pixel array).

In some embodiments, the sub-pixels have at least lateral dimension that is equal to or less than 20 microns. In some embodiments, the sub-pixels have at least one lateral dimension that is equal to or less than 10 microns. In some embodiments, the sub-pixels have at least one lateral dimension that is equal to or less than 5 microns.

In some embodiments, the color-emitting material for all same-color sub-pixels are directly deposited using a shadow mask having a membrane through which rectangular-shaped apertures are formed, where the apertures are arranged such that the apertures of every other row are offset by one sub-pixel position. In the illustrative embodiment, the structural material of the membrane comprises a metal and the apertures are 5 microns wide by 20 microns long. In some embodiments, the apertures are arranged such that the apertures of each subsequent row are offset from that of its preceding row by one sub-pixel position.

In some embodiments, the structural material of the membrane comprises a material other than a metal, such as graphene, an inorganic semiconductor (e.g., silicon, silicon, silicon carbide, germanium, a compound semiconductor, etc.), a dielectric (e.g., silicon nitride, silicon-rich nitride, silicon oxynitride, etc.), a silicon-based insulator, a titanium-based insulator, a ceramic, and the like. In some embodiments, the structural material includes a plurality of material layers.

In some embodiments, the apertures have a shape other than a rectangle, such as a square, triangle, circle, trapezoid, octagonal, irregular shape, and the like.

An embodiment in accordance with the present disclosure is an organic light-emitting diode (OLED) display comprising: a pixel array in which each pixel of the pixel array includes a first sub-pixel that emits light of a first color, a second sub-pixel that emits light of a second color, and a third sub-pixel that emits light of a third color; wherein each pixel is located in a different pixel-region of an array of pixel-regions, each pixel-region of the array thereof having a first sub-pixel position, a second sub-pixel position, and a third sub-pixel position, the first, second, and third sub-pixel positions being arranged linearly along a first direction; and wherein the display is characterized by: the first sub-pixel being at a different one of the first, second, and third sub-pixel positions in each pixel of a pair of adjacent pixels along a second direction that is orthogonal to the first direction; the second sub-pixel being at a different one of the first, second, and third sub-pixel positions in each pixel of the pair of adjacent pixels; and the third sub-pixel being at a different one of the first, second, and third sub-pixel positions in each pixel of the pair of adjacent pixels.

Another embodiment in accordance with the present disclosure is a method for forming an organic light-emitting diode (OLED) display comprising a pixel array in which each pixel includes a first sub-pixel that emits light of a first color, a second sub-pixel that emits light of a second color, and a third sub-pixel that emits light of a third color, and wherein the method comprises: providing a substrate having a pixel-region array, wherein each pixel-region of the array thereof corresponds to a different pixel of the pixel array, and wherein each pixel-region includes a first electrode located at a first sub-pixel position, a second electrode located at a second sub-pixel position, and a third electrode located at a third sub-pixel position, the first, second, and third sub-pixel positions being arranged linearly along a first direction; aligning the substrate and a first shadow mask comprising a first aperture array, each aperture of the first array thereof being located within a different mask region of a mask-region array that has a one-to-one correspondence with the pixel-region array; and depositing a first light-emitting material onto the substrate through the first shadow mask; wherein the method is characterized by providing the first shadow mask such that the apertures within the mask-regions of every pair of adjacent mask-regions along a second direction that is orthogonal with the first direction are located at different sub-pixel positions selected from the group consisting of the first, second, and third sub-pixel positions.

### BRIEF DESCRIPTION OF THE DRAWINGS

FIGS. 1A-B depict schematic drawings of a color-filter-based OLED display pixel and a “side-by-side,” direct-color-emission OLED display pixel, respectively.

FIG. 2A depicts a schematic drawing of a top view of a portion of a high-resolution AMOLED display in accordance with the prior art.

FIG. 2B depicts a schematic drawing of a top view of a representative individual pixel 204(i,j) of display 200.

FIG. 3 depicts a schematic drawing of a top view of a portion of a prior-art shadow mask configured for defining the color-emitting regions of the sub-pixels of a display using two depositions.

FIG. 4 depicts a schematic drawing of a top view of a portion of a display formed using two deposition operations for each color sub-pixel in its pixel array.

FIG. 5 depicts an OLED display in accordance with the present disclosure.

FIG. 6 depicts a shadow mask suitable for depositing the color-emitting material for all same-color sub-pixels of an OLED display in accordance with the present disclosure.

FIG. 7 depicts a schematic drawing of a top view of a portion of display 500 formed using a single deposition operation for each color sub-pixel in its pixel array via shadow mask 600.

FIGS. 8A-D depict schematic drawings of portions of different exemplary shadow-masks that include alternative apertures in accordance with the present disclosure.

FIG. 9 depicts a schematic drawing of a portion of an alternative shadow mask in accordance with the present disclosure.

FIG. 10 depicts a schematic drawing of a portion of a pixel array formed in using a single deposition operation for each array of same-color pixels using shadow mask 900.

### DETAILED DESCRIPTION

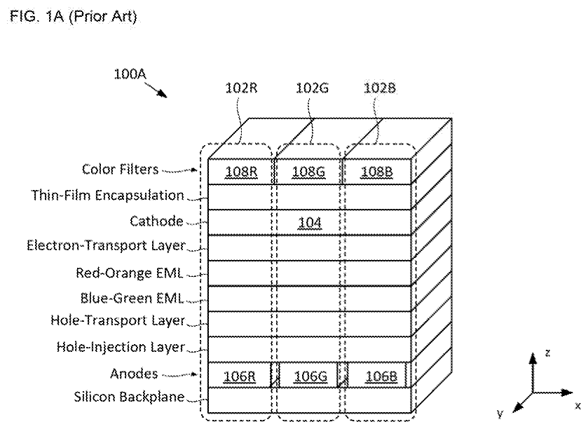

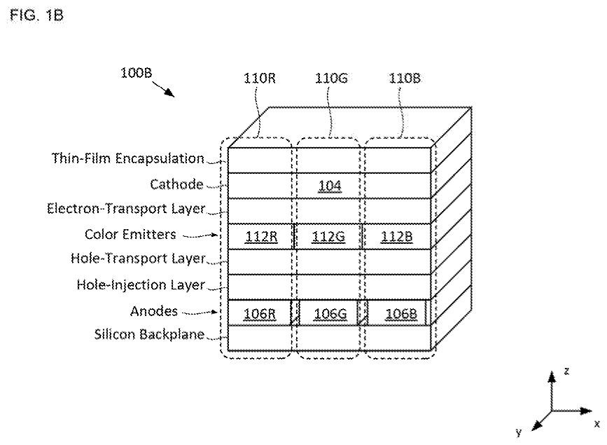

FIGS. 1A-B depict schematic drawings of a color-filter-based OLED display pixel and a “side-by-side,” direct-color-emission OLED display pixel, respectively.

Pixel 100A is a conventional color-filter-based OLED pixel that includes red, green, and blue sub-pixels 102R, 102G, and 102B. Each of sub-pixels 102R, 102G, and 102B includes its respective portion of the layers of the OLED residing between cathode 104 and independently addressable anodes 106R, 106G, and 106B and a color filter that transmits only one of red, green, and blue light (i.e., filters 108R, 108G, and 108B).

When each of sub-pixels 102R, 102G, and 102B is energized, it generates substantially white light that passes through its respective color filter, which passes only the desired color of that sub-pixel. As a result, much of the light generated by the sub-pixels of pixel 100A is wasted. Furthermore, the “unwanted” optical energy is absorbed by the filter and typically converted to thermal energy. Since this excess heat can cause significant operational and reliability issues, it must be conducted away from the pixel area, increase the complexity and cost of such displays.

In contrast, pixel 100B is a “side-by-side” pixel that includes individually addressable sub-pixels 110R, 110G, and 110B, each of which is a different OLED emitting region configured to emit a different color of light. Sub-pixels 110R, 110G, and 110B include light-emitting materials 112R, 112G, and 112B, which, when energized by current flow between cathode 104 and its respect anode, emit red, green, and blue light, respectively.

As noted above, pixel 100B is more efficient than pixel 100A because no emitted light is wasted; red, green or blue is directly emitted only when red-light-emitting OLED 108R, green-light-emitting OLED 108G, and blue-light-emitting OLED 108B, respectively, is energized.

Unfortunately, color-emitting OLED material is organic and, therefore, cannot be patterned using conventional lithography and etching techniques. As a result, the color-emitting regions of OLED-based sub-pixels must be formed by depositing the color-emitting material onto their respective anodes through a shadow mask that has an appropriate pattern of apertures. As discussed above, however, for high-resolution (>2500 pixels per inch) OLED displays, the distance between sub-pixels is extremely small leaving very little structural mask material between them. Furthermore, since the sub-pixels of high-resolution displays have small lateral dimensions (typically <20 microns), the thickness of the structural layer in which the apertures are formed must be thin (typically about one micron) to avoid shadowing effects that can cause non-uniform thickness of the deposited material. As a result, the extremely small regions of very thin structural material of such masks makes them complicated to fabricate, expensive, and extremely fragile.

To mitigate the problems associated with high-density shadow masks, in the prior art, the pattern of sub-pixels of each color is normally formed in multiple depositions, where each deposition is performed using a shadow mask having a sparser pattern of apertures containing only fraction of the aperture pattern required to create a complete sub-pixel pattern.

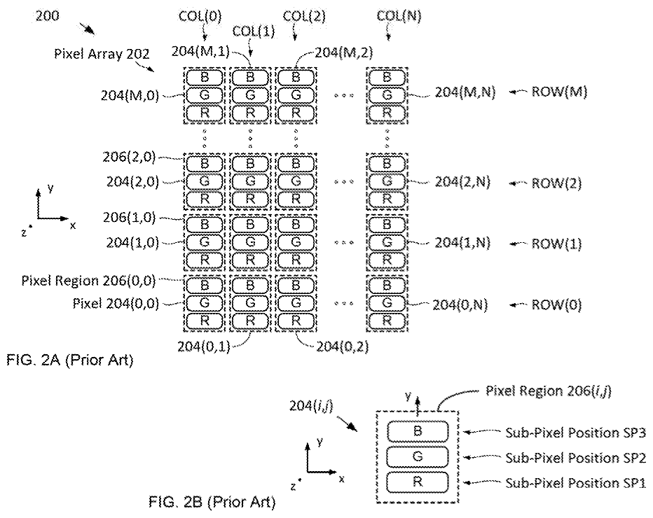

FIG. 2A depicts a schematic drawing of a top view of a portion of a high-resolution AMOLED display in accordance with the prior art. Display 200 includes a two-dimensional ordered array of pixels 204(0,0) through 204(M,N), where M and N have any practical values. Pixels 204(0,0) through 204(M,N) (referred to, collectively, as pixels 204) are located within pixel regions 206(0,0) through 206(M,N) (referred to, collectively, as pixel regions 206). Pixel regions 206 are arranged in a two-dimensional array having rows ROW(0) through ROW(M) and columns COL(0) through COL(N).

FIG. 2B depicts a schematic drawing of a top view of a representative individual pixel 204(i,j) of display 200.

Each of pixels 204 includes sub-pixels R, G, and B, which emit red, green, and blue, respectively. Sub-pixels R, G, and B are arranged in a 1×3 linear array within a pixel region 206 such that sub-pixel R is located at sub-pixel position SP1, sub-pixel G is located at sub-pixel position SP2, and sub-pixel B is located at sub-pixel position SP3. In the depicted example, sub-pixel positions SP1, SP2, and SP3 are arranged along the y-direction such that the 1×3 array is aligned with the columns of pixel array 202.

As seen from FIGS. 2A-B, every sub-pixel of the same color is located in the same sub-pixel position within its respective pixel region 206. Specifically, in the depicted example, every sub-pixel R is located in sub-pixel position SP1, every sub-pixel G is located in sub-pixel position SP2, every sub-pixel B is located in sub-pixel position SP3 within their respective pixel regions.

As a result, adjacent sub-pixels of the same color are separated by an extremely small gap along the x-direction. This small gap between adjacent pixels makes it extremely difficult to form all of the sub-pixels of display 200 at one time using a single deposition through a shadow mask that includes an aperture for every sub-pixel of a single color.

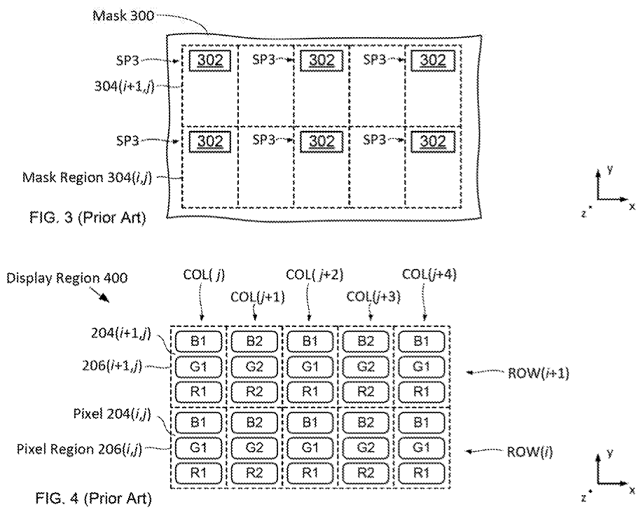

FIG. 3 depicts a schematic drawing of a top view of a portion of a prior-art shadow mask configured for defining the color-emitting regions of the sub-pixels of a display using two depositions. Shadow mask 300 includes an array of apertures 302, each of which resides within a different one of mask regions 304(0,0) through 304(M,N) (referred to, collectively as mask regions 304). FIG. 3 depicts an area of shadow mask 300 that corresponds to a 2×5 sub-array of pixel regions 206.

Each of apertures 302 is a rectangular opening in a thin (˜1-micron thick) structural layer of shadow mask 300 that allows the passage of vaporized color-emitting material. The size and shape of apertures 302 determines the size and shape of the sub-pixels formed by direct deposition through them.

Shadow mask 300 includes a two-dimensional array of mask regions 304, which correspond to pixel regions 206 such that the size and arrangement of mask regions 304 is the same as the size and arrangement of the pixel regions. As a result, the array of mask regions 304 is also characterized by the same rows ROW(0) through ROW(M) and same columns COL(0) through COL(N).

Shadow mask 300 is configured such that all of its apertures are in the same sub-pixel position and only the mask regions of every other column of mask-region array includes an aperture 302. In other words, along each row of shadow mask 300, only every other mask region includes an aperture. As a result, the spacing between adjacent apertures is approximately twice that of the pixel spacing of display 200, which enhances the structural integrity of shadow mask 300.

To form a complete array of same-color sub-pixels in display 200 using of shadow mask 300, therefore, two separate deposition operations are required: one in which shadow mask 300 is aligned with the even-numbered columns of pixel array 202 (i.e., columns COL(0), COL(2), COL(4), and so on); and one in which shadow mask 300 is aligned with the odd-numbered columns of pixel array 202 (i.e., columns COL(1), COL(3), COL(5), and so on).

FIG. 4 depicts a schematic drawing of a top view of a portion of a display formed using two deposition operations for each color sub-pixel in its pixel array. Display region 400 is a portion of display 200 that shows a 10-pixel region of pixel array 202—specifically, pixels 204(i,j) through 204(i+1,j+4), which are located in pixel regions 206(i,j) through 206(i+1,j+4), respectively.

Each of pixels 204 includes a red sub-pixel that has been formed at sub-pixel position SP1 in its respective pixel region 206, a green sub-pixel formed at sub-pixel position SP2, and a blue sub-pixel formed at sub-pixel position SP3. However, the red sub-pixels include sub-pixels R1 and R2, where R1 denotes deposition of its red-light-emitting material in a first deposition and R2 denotes deposition of its red-light-emitting material in a second deposition. In similar fashion, the green sub-pixels include sub-pixels G1 and G2, formed in separate depositions of their respective green-light-emitting material, and the blue sub-pixels include sub-pixels B1 and B2, formed in separate depositions of their respective blue-light-emitting material.

As discussed above, the need for multiple depositions for each color-emitting material increases fabrication time, decreases the product throughput, and wastes material, thereby increasing fabrication cost. Furthermore, the use of multiple depositions for each color sub-pixel can introduce more color crosstalk between different colors during the repeated deposition with fine mask.

It is an aspect of the present disclosure, however, that a pixel array having a non-uniform arrangement of sub-pixels enables the use of a shadow mask capable of defining the color-emitting material for all of the same-color sub-pixels included in a pixel array in a single deposition. As a result, the teachings of the instant disclosure mitigate many of the challenges associated with side-by-side OLED displays of the prior art.

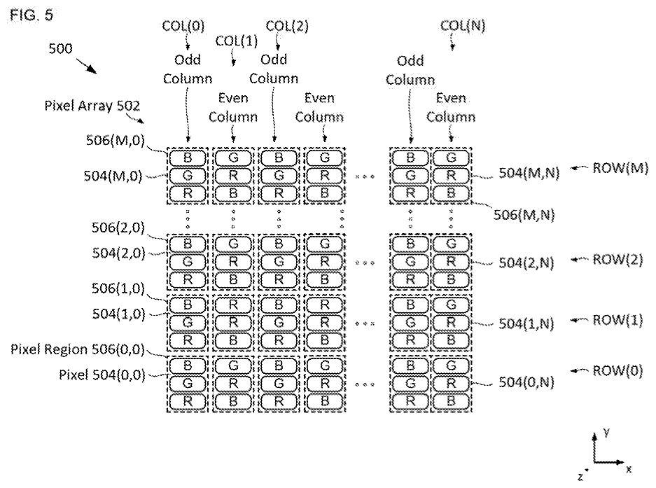

FIG. 5 depicts an OLED display in accordance with the present disclosure. Display 500 includes pixel array 502, which includes a two-dimensional ordered array of pixels 504(0,0) through 504(M,N) (referred to, collectively, as pixels 504). In the depicted example, the arrangement of the pixels of pixel array 502 is analogous to the arrangement of the pixels of pixel array 202. In other words, pixels 502 are arranged in rows ROW(0) through ROW(M) and columns COL(0) through COL(N), in similar fashion to pixel array 202. It should be noted, however, that pixel array 502 can have any practical arrangement of pixels 504 without departing from the scope of the present disclosure.

Each pixel 504 includes three sub-pixels that emit red, green, and blue light, respectively, and is defined within a corresponding pixel region 506 having sub-pixel positions SP1, SP2, and SP3, which are aligned along the y-direction to define a 1×3 array. In contrast to pixel array 202, however, the location of the red, green, and blue sub-pixels within pixels 504 is not uniform across pixel array 502. In other words, the same-color sub-pixels are not in the same sub-pixel positions in every pixel region 506.

In the depicted example, along the x-direction, which is aligned with rows ROW(0) through ROW(M), the position of red sub-pixels R alternates between sub-pixel positions SP1 and SP2, the position of green sub-pixels G alternates between sub-pixel positions SP2 and SP3, and the position of blue sub-pixels B alternates between sub-pixel positions SP3 and SP1. In other words, in each even column of pixel array 502 (i.e., columns COL(0), COL(2), COL(4), and so on), sub-pixels R, G, and B are in sub-pixel positions SP1, SP2, and SP3, respectively, which in each odd column of pixel array 502 (i.e., columns COL(1), COL(3), COL(5), and so on), sub-pixels R, G, and B are in sub-pixel positions SP2, SP3, and SP1, respectively.

By locating same-color sub-pixels at different sub-pixel positions in adjacent columns of pixel array 502, the same-color sub-pixels are more sparsely arranged. As a result, all of the same-color sub-pixels of pixel array 502 can be defined in a single deposition operation using a shadow mask that has more structural material between its apertures and, therefore, improved structural integrity as compared to prior-art shadow masks.

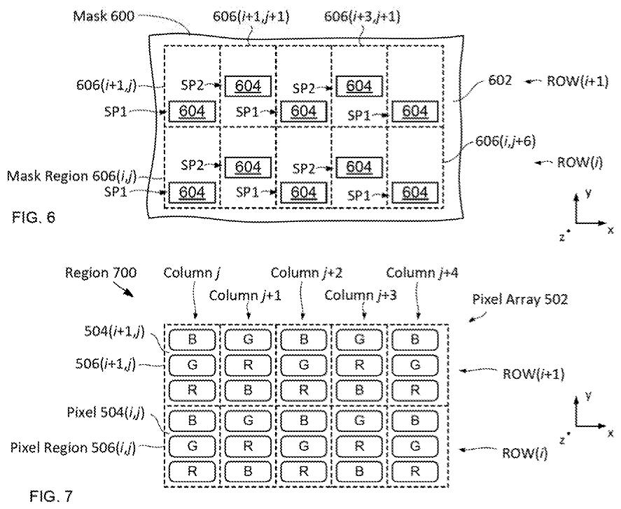

FIG. 6 depicts a shadow mask suitable for depositing the color-emitting material for all same-color sub-pixels of an OLED display in accordance with the present disclosure. Shadow mask 600 includes membrane 602 and apertures 604 formed through the thickness of the membrane.

Membrane 602 is a layer of silicon-rich silicon nitride having a thickness of approximately 1 micron. Membrane 602 is suspended above a central opening formed in a silicon handle substrate (not shown) the functions as a structural frame for the membrane. The composition of the silicon-rich silicon nitride is controlled such that the residual stress in the material is tensile and approximately 300 MPa. In some embodiments, membrane 602 comprises a different suitable structural material. In some embodiments, membrane 602 is a composite membrane comprising one or more layers of different materials, each having a different residual stress. In such embodiments, the different residual stresses of the layers give rise to a stress gradient through the thickness of the membrane that causes a mechanical pre-bias that mitigates gravity-induced sag of the membrane during use. Membranes suitable for use in accordance with the present disclosure are described in detail in U.S. patent application Ser. Nos. 15/968,443 and 15/968,325, each of which is incorporated herein by reference.

In some embodiments, membrane 602 is other than a suspended dielectric material, such as a thin metal sheet through which apertures are formed. In some embodiments, membrane 602 includes a different material, such as graphene, an inorganic semiconductor (e.g., silicon, silicon, silicon carbide, germanium, a compound semiconductor, etc.), a dielectric (e.g., silicon nitride, silicon-rich nitride, silicon oxynitride, etc.), a silicon-based insulator, a titanium-based insulator, a ceramic, and the like.

Apertures 604 are rectangular through-holes formed completely through the thickness of membrane 602 within mask regions 606(0,0) through 606(M,N) (referred to, collectively, as mask regions 606). Mask 600 is configured such that there is an aperture 604 located in every mask region 606 and mask regions 606 have a one-to-one correspondence with pixel regions 506 of pixel array 502. As a result, mask 600 includes an aperture for each and every pixel of pixel array 502 and mask region 606 are arranged in a two-dimensional ordered array characterized by rows ROW(0) through ROW(M) and columns COL(0) through COL(N).

In the depicted example, in each even column of the array of mask regions 606 (i.e., columns COL(0), COL(2), COL(4), and so on), apertures 604 are located at sub-pixel position SP1, while in each odd column of the array of mask regions 606 (i.e., columns COL(1), COL(3), COL(5), and so on), apertures 604 are located at sub-pixel position SP2.

FIG. 7 depicts a schematic drawing of a top view of a portion of display 500 formed using a single deposition operation for each color sub-pixel in its pixel array via shadow mask 600. Display region 700 is a portion of display 500 that includes a 10-pixel region of pixel array 502—specifically, pixels 504(i,j) through 504(i+1,j+4), which are located in pixel regions 506(i,j) through 506(i+1,j+4), respectively.

As seen in the figure, red sub-pixel R is located at alternating sub-pixel positions in adjacent columns across pixel array 502. In the even-numbered columns of the pixel array, sub-pixel R is located at sub-pixel position SP1 in its respective pixel region 206, green sub-pixel G located at sub-pixel position SP2, and blue sub-pixel B is located at sub-pixel position SP3, while in odd-numbered columns, sub-pixel R is located at sub-pixel position SP2 in its respective pixel region 206, green sub-pixel G located at sub-pixel position SP3, and blue sub-pixel B is located at sub-pixel position SP1.

By applying a non-uniform sub-pixel arrangement to a pixel array, the teachings of the present disclosure afford several significant advantages over the prior art, including:
i. improved pixel-to-pixel uniformity; or
ii. significantly reduced deposition time for the sub-pixel pattern of each color-emitting material; or
iii. higher fabrication throughput; or
iv. less material waste; or
v. any combination of i, ii, iii, and iv.

Returning now to shadow mask 600, in the depicted example, each of apertures 604 has lateral dimensions of 5 microns by 20 microns; however, any practical lateral shape or dimensions can be used for apertures 604 without departing from the scope of the present disclosure.

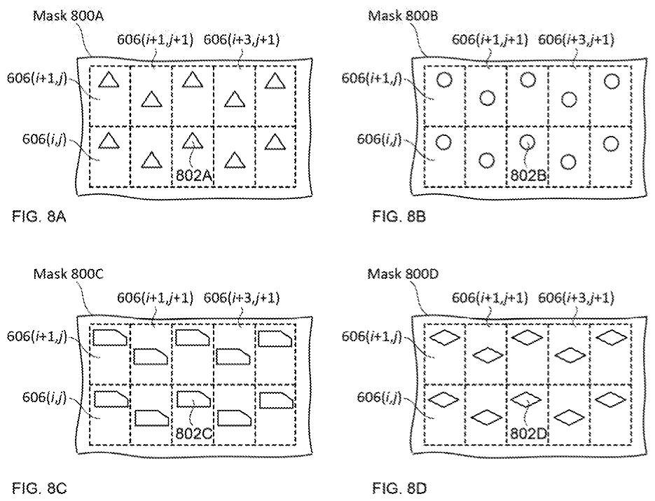

FIGS. 8A-D depict schematic drawings of portions of different exemplary shadow-masks that include alternative apertures in accordance with the present disclosure.

Mask region 800A includes apertures 802A, each of which is a triangular aperture having sides of approximately 10 microns.

Mask region 800B includes apertures 802B, each of which is a circular aperture having a diameter of approximately 10 microns.

Mask region 800C includes apertures 802C, each of which is an irregularly shaped aperture having an area of approximately 100 microns².

Mask region 800D includes apertures 802D, each of which is a trapezoidal aperture having sides of approximately 10 microns.

Although the embodiments described herein realize pixels having sub-pixels that are arranged in a 1×3 array that is aligned with the columns of the pixel array, in some embodiments, the sub-pixel positions are arranged along the x-direction such that the 1×3 array is aligned with the rows of a pixel array. As will be apparent to one skilled in the art, in such embodiments, the same principles described above can be used with suitable orientation changes to realize a shadow mask that enables deposition of all same-color sub-pixels in a single deposition without compromising the structural integrity of the shadow mask.

Furthermore, although pixel array 502 is arranged such that the position of each same-color sub-pixel simply alternates between two sub-pixel position along each of its rows, it will be clear to one skilled in the art, after reading this Specification, that other arrangements in which the same-color sub-pixels are not adjacent to one another along each row are within the scope of this disclosure. For example, in some embodiments, same-color sub-pixels are arranged such that they index by one sub-pixel position from pixel to pixel along each row (i.e., they are arranged diagonally in a pixel array).

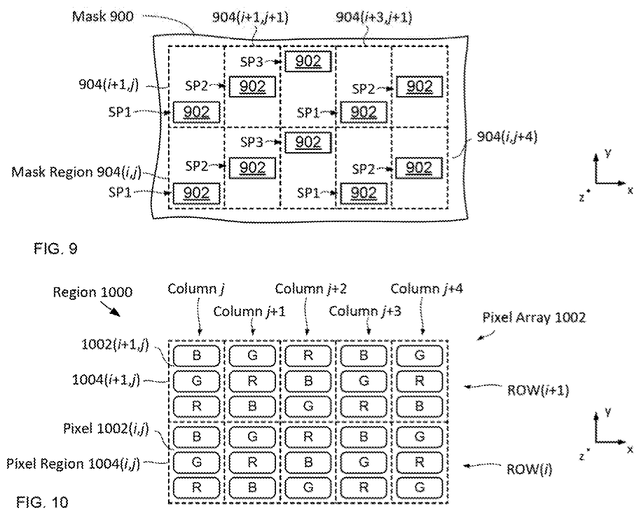

FIG. 9 depicts a schematic drawing of a portion of an alternative shadow mask in accordance with the present disclosure. Shadow mask 900 is analogous to shadow mask 600 described above and includes apertures 902, each of which is located in a different one of mask regions 904(0,0) through 904(M,N).

Apertures 902 are analogous to apertures 502 described above; however, apertures 902 are arranged such that their position indexes by one sub-pixel position from mask region to mask region along each of rows ROW(0) through ROW(M).

As a result, apertures 902 index one sub-pixel location from mask region to mask region along each row of mask regions such that the apertures are arranged diagonally over the extent of shadow mask 900. In every set of three adjacent columns, therefore, apertures are located once at each of the three different sub-pixel positions SP1, SP2, and SP3. For example, apertures 902 are located at sub-pixel position SP1 in COL(j), at sub-pixel position SP2 in COL(j+1), and at sub-pixel position SP3 in COL(j+2), at sub-pixel position SP1 in COL(j=3), and so on.

FIG. 10 depicts a schematic drawing of a portion of a pixel array formed in using a single deposition operation for each array of same-color pixels using shadow mask 900. Since the position of each same-color pixel is determined by the location of aperture 902 in each mask region 904, same-color pixels are arranged diagonally through the extent of pixel array 1002.

Specifically, in each row ROW(i), where 1=1 through M, across adjacent pixel regions 1004(i,j), 1004(i,j+1), and 1004(i,j+2), red sub-pixels R are sequentially located in sub-pixel positions SP1, SP2, and SP3, green sub-pixels G are sequentially located in sub-pixel positions SP2, SP3, and SP1, and blue sub-pixels B are sequentially located in sub-pixel positions SP3, SP1, and SP2.

As will be apparent to one skilled in the art, after reading this Specification, the two sub-pixel arrangements described herein represent only some of the possible sub-pixel arrangements in accordance with the present disclosure.

It is to be understood that the disclosure teaches just some embodiments in accordance with the present invention and that many variations of the invention can easily be devised by those skilled in the art after reading this disclosure and that the scope of the present invention is to be determined by the following claims.

What is claimed is:

1. An organic light-emitting diode (OLED) display comprising:
a pixel array in which each pixel of the pixel array includes a first sub-pixel that emits light of a first color, a second sub-pixel that emits light of a second color, and a third sub-pixel that emits light of a third color;
wherein each pixel is located in a different pixel-region of an array of pixel-regions, each pixel-region of the array thereof having a first sub-pixel position, a second sub-pixel position, and a third sub-pixel position, the first, second, and third sub-pixel positions being arranged linearly along a first direction; and
WHEREIN THE DISPLAY IS CHARACTERIZED BY:
the first sub-pixel being at a different one of the first, second, and third sub-pixel positions in the pixels of each pair of adjacent pixels along a second direction that is orthogonal to the first direction;
the second sub-pixel being at a different one of the first, second, and third sub-pixel positions in the pixels of each pair of adjacent pixels; and
the third sub-pixel being at a different one of the first, second, and third sub-pixel positions in the pixels of each pair of adjacent pixels.

2. The display of claim 1 wherein, in each pair of adjacent pixels along the second direction, the location of the first sub-pixel alternates between the first sub-pixel position and one of the second and third sub-pixel positions, the location of the second sub-pixel alternates between the second sub-pixel position and one of the first and third sub-pixel positions, and the location of the third sub-pixel alternates between the third sub-pixel position and one of the second and third sub-pixel positions.

3. The display of claim 1 wherein the pixels are numbered from 0 to N along a second direction that is orthogonal to the first direction, and wherein, in each even-numbered pixel along the second direction, the first sub-pixel is in the first sub-pixel position and the second sub-pixel is in the second sub-pixel position, and in each odd numbered pixel along the second direction, the first sub-pixel is in the second sub-pixel position and the second pixel is in the third sub-pixel position.

4. The display of claim 1 wherein, in each group of three adjacent pixels along the second direction, the first sub-pixel is located in each of the first, second, and third sub-pixel positions once, the second sub-pixel is located in each of the first, second, and third sub-pixel positions once, and the third sub-pixel is located in each of the first, second, and third sub-pixel positions once.

5. The display of claim 1 wherein the display has a pixel resolution of at least 2500 pixels per inch in each of the first and second directions.

6. The display of claim 1 wherein each of the first, second, and third sub-pixels has a dimension along one of the first and second directions that is less than or equal to 10 microns.

7. The display of claim 1 wherein each of the first, second, and third sub-pixels has a dimension along one of the first and second directions that is less than or equal to 5 microns.

8. The display of claim 1 wherein each of the first, second, and third sub-pixels has a shape that is selected from the group consisting of a rectangle, a square, a triangle, a trapezoid, an octagon, and an irregular shape.

9. A method for forming an organic light-emitting diode (OLED) display comprising a pixel array in which each pixel includes a first sub-pixel that emits light of a first color, a second sub-pixel that emits light of a second color, and a third sub-pixel that emits light of a third color, and wherein the method comprises:
providing a substrate having a pixel-region array, wherein each pixel-region of the array thereof corresponds to a different pixel of the pixel array, and wherein each pixel-region includes a first electrode located at a first sub-pixel position, a second electrode located at a second sub-pixel position, and a third electrode located at a third sub-pixel position, the first, second, and third sub-pixel positions being arranged linearly along a first direction;
aligning the substrate and a first shadow mask comprising a first aperture array, each aperture of the first array thereof being located within a different mask region of a mask-region array that has a one-to-one correspondence with the pixel-region array; and
depositing a first light-emitting material onto the substrate through the first shadow mask;
WHEREIN THE METHOD IS CHARACTERIZED BY providing the first shadow mask such that the apertures within the mask-regions of every pair of adjacent mask-regions along a second direction that is orthogonal with the first direction are located at different sub-pixel positions selected from the group consisting of the first, second, and third sub-pixel positions.

10. The method of claim 9 further comprising:
aligning the substrate and a second shadow mask comprising a second aperture array, each aperture of the second array thereof being located within a different mask region of the mask-region array, wherein second aperture array is configured such that the apertures within the mask-regions of every pair of adjacent mask-regions along the second direction are located at different sub-pixel positions selected from the group consisting of the first, second, and third sub-pixel positions;
depositing a second light-emitting material onto the substrate through the second shadow mask;
aligning the substrate and a second shadow mask comprising a third aperture array, each aperture of the third array thereof being located within a different mask region of the mask-region array, wherein third aperture array is configured such that the apertures within the mask-regions of every pair of adjacent mask-regions along the second direction are located at different sub-pixel positions selected from the group consisting of the first, second, and third sub-pixel positions; and
depositing a third light-emitting material onto the substrate through the third shadow mask.

11. The method of claim 10 wherein the first shadow mask, the second shadow mask, and the third shadow mask are the same shadow mask, and wherein

12. The method of claim 9 further comprising providing the first shadow mask such that, in each pair of adjacent mask-regions along the second direction, the location of the aperture alternates between the first sub-pixel position and one of the second and third sub-pixel positions.

13. The method of claim 9 further comprising providing the first shadow mask such that, for each group of three adjacent mask-regions along the second direction, the aperture is located in each of the first, second, and third sub-pixel positions once.

14. The method of claim 9 further comprising providing the first shadow mask such that at least one aperture of the first aperture array has a dimension along one of the first and second directions that is less than or equal to 10 microns.

15. The method of claim 9 further comprising providing the first shadow mask such that the shape of at least one aperture of the first aperture array is a rectangle, square, triangle, trapezoid, octagon, or irregular.
